(19) United States
(12) Patent Application Publication
(10) Pub. No.: US 2026/0059779 A1
(43) Pub. Date: Feb. 26, 2026

(54) GATE-ALL-AROUND DEVICES AND METHOD FOR MANUFACTURING SAME

(71) Applicant: Taiwan Semiconductor Manufacturing Company, Ltd., Hsin-Chu (TW)

(72) Inventors: Tze-Chung Lin, Hsinchu City (TW); Fang-Wei Lee, Hsinchu City (TW); Chia-Chien Kuang, Taipei City (TW); Pinyen Lin, Rochester, NY (US)

(21) Appl. No.: 18/815,259

(22) Filed: Aug. 26, 2024

(51) Int. Cl. H01L 29/66; H01L 21/324; H01L 29/06; H01L 29/161; H01L 29/423; H01L 29/775; H01L 29/786

(52) U.S. Cl. CPC H10D 30/014; H01L 21/324; H10D 62/116; H10D 64/015; H10D 30/43; H10D 30/6735; H10D 30/6757; H10D 62/121; H10D 62/832

(57) ABSTRACT

A method of the present disclosure includes forming a stack that includes channel layers interleaved by sacrificial layers, patterning the stack to form a fin-shaped structure, forming a dummy gate stack over a channel region of the fin-shaped structure, recessing a source/drain region of the fin-shaped structure to form a trench, removing the sacrificial layers in the channel region to release the channel layers as channel members, partially filling a space vertically stacked between adjacent two of the channel members with a dielectric dummy layer, performing a treatment to expand the dielectric dummy layer to fully fill the space, laterally recessing the dielectric dummy layer to form recesses, forming inner spacers in the recesses, forming a source/drain feature in the trench, removing the dummy gate stack, removing the dielectric dummy layer to release the channel members, and forming a gate structure to wrap around the channel members.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. As GAA devices continue to scale, challenges have arisen. For example, the existing structures and fabrication technologies have various issues, which includes excessive impurity diffusion, increased built-in stress, undesired capacitance, device degradation, scaling limit by overlap requirement, and other structure-related issues and/or process-related issues especially as device size is scaled down. Although existing structure and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-30 illustrate fragmentary cross-sectional views of a work-in-progress (WIP) structure during a fabrication process according to the method of FIG. 1, according to one or more aspects of the present disclosure.

FIG. 31 illustrates a diagram of etch rate versus germanium atomic percentage in a selective etching process, according to one or more aspects of the present disclosure.

FIGS. 32A and 32B illustrate a dielectric dummy layer at molecular level before and after a cross-linking treatment, respectively, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and manufacturing methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. Ideally, due to the different material compositions, a large etch selectivity between the sacrificial materials (e.g., SiGe) and the nanostructures (e.g., Si) should have safeguarded the nanostructures from etching loss during the removal of the sacrificial materials. However, atoms other than silicon (e.g., Ge) in the sacrificial materials may diffuse into the nanostructures as impurities during annealing processes, such as the annealing processes in forming the epitaxial source/drain features. The diffusion of the impurities lowers the etching selectivity. As a result, the nanostructures may suffer from etching loss during the removal of the sacrificial materials. For example, top and bottom surfaces of the nanostructures may become non-flat and have a curvature profile due to extra etching loss. The curvature profile of the top and bottom surfaces of the nanostructures may cause gate structure profile variation and result in device performance non-uniformity.

The present disclosure provides methods for forming a GAA transistor. In an example process, a fin-shaped structure with channel layers and sacrificial layers is formed over a substrate. Intermixing layers are formed between the adjacent ones of the channel layers and the sacrificial layers. Compared with the sacrificial layers that includes a relatively higher germanium concentration (also referred to as mole fraction or germanium atomic percentage (Ge %)), the intermixing layers have a relatively lower germanium concentration. After formation of a dummy gate stack over a channel region of the fin-shaped structure, at least one gate spacer is formed over the dummy gate stack. Source/drain regions of the fin-shaped structure are recessed. The sacrificial layers are removed to release the channel layers as channel members in a selective etching process. The selective etching process is tuned to have a high etching contrast between the sacrificial layers and the intermixing layers due to the difference in germanium concentration, such that the intermixing layers remain and safeguard the flatness of the channel members. A dielectric dummy layer is then deposited to wrap around each of the channel members in a suitable deposition process, such as an atomic layer deposition (ALD) process. A cross-linking treatment may be applied to remove gaps and/or seams from the dielectric dummy layer. The dielectric dummy layer is then selectively and partially recessed to form inner spacer recesses between the plurality of channel members. An inner spacer layer is deposited over the inner spacer recesses. The deposited inner spacer layer is etched back to form inner spacer features. Source/drain features are then formed over the source/drain recesses. After selective removal of the dummy gate stack, the dielectric dummy layer is selectively removed to release the channel members again. A gate structure is then formed to wrap around each of the channel members.

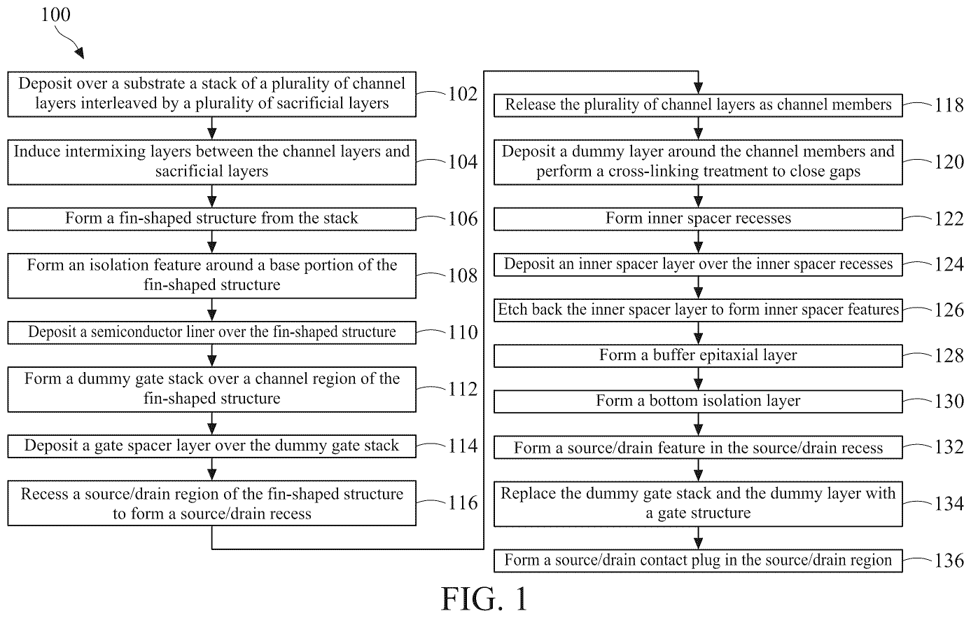

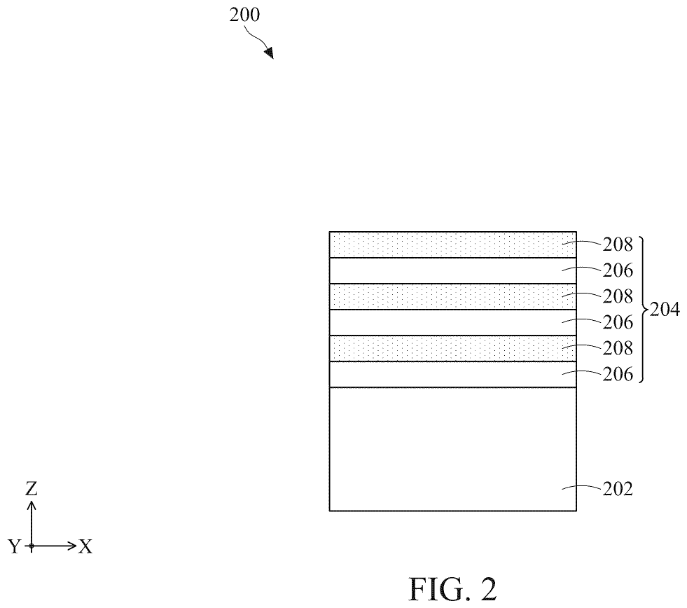

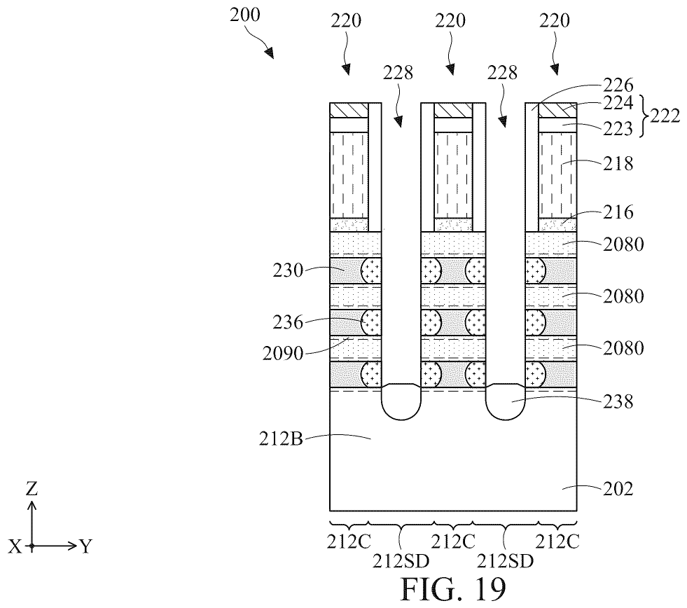

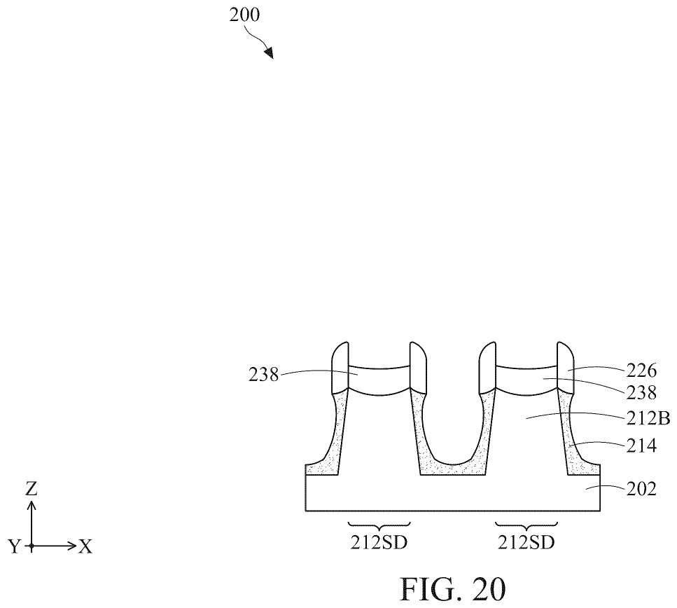

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-31, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-31 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the semiconductor device 200. As shown in FIG. 2, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

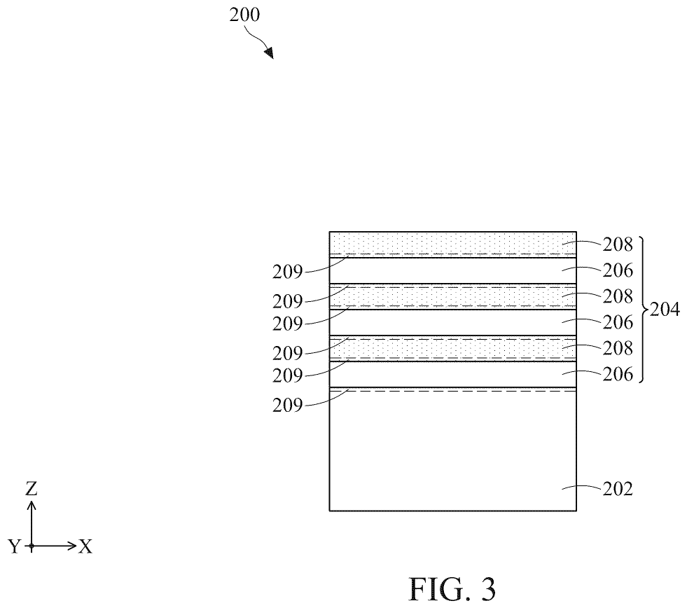

Referring to FIGS. 1 and 3, method 100 includes a block 104 where a thermal treatment is performed to induce intermixing layers 209 between the adjacent ones of the channel layers 208 and the sacrificial layers 206. An intermixing layer 209 is also formed between the bottommost sacrificial layer 206 and the top portion of the substrate 202. In some embodiments of method 100, block 104 is optional. For example, block 104 may be skipped, and method 100 relies on one or more thermal treatments in subsequent processes to promote the intermixing layers 209. The thermal treatment accelerates the diffusion of germanium atoms from the sacrificial layers 206 into the channel layers 208 and thus forms the intermixing layers 209 therebetween. The intermixing layers 209 are rich in silicon and include a small portion of germanium. The Ge % in the intermixing layers 209 may be in a range between about 0.02% and about 13%, in some embodiments. The Ge % in the intermixing layers 209 is less than that in the sacrificial layers 206 to ensure a proper etching contrast in a later selective etching process. For example, a ratio of the Ge % in the intermixing layers 209 and that of the sacrificial layers 206 may range between about 1:100 and about 1:5. This ratio is neither arbitrary nor trivial. As discussed in further detail below with reference to block 118, the ratio ensures a high etching contrast during the selective removal of the sacrificial layers 206. The thickness of the intermixing layers 209 may be in the range between about 0.1 nm and about 2 nm, in some embodiments. The thickness of the intermixing layers 209 can be controlled by the proper temperature and duration of the thermal treatment.

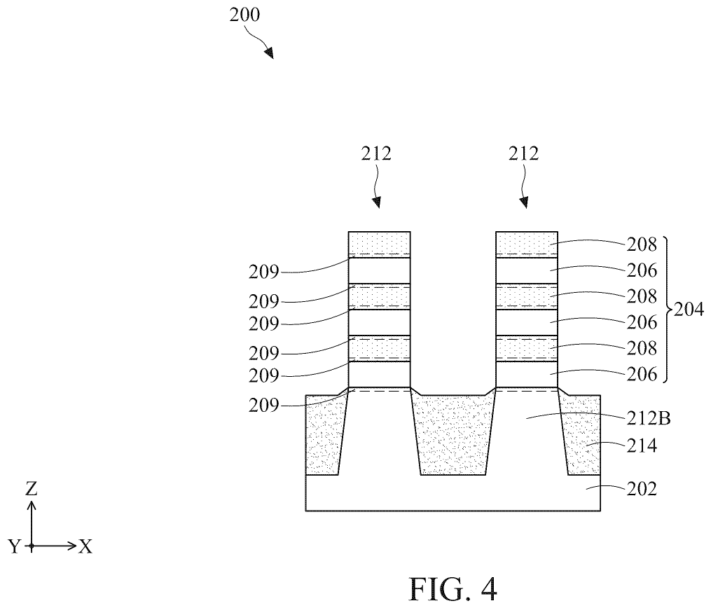

Referring to FIGS. 1 and 4, method 100 includes a block 106 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 4, the etching process at block 106 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 extends vertically along the Z direction and lengthwise along the Y direction. As shown in FIG. 4, the fin-shaped structure 212 includes a fin-shaped base 212B patterned from the substrate 202 and the patterned stack 204 disposed directly over the fin-shaped base 212B. In some instances, a width of the fin-shaped structures 212 measured along the Y direction may be between about 3 nm and about 20 nm.

Still referring to FIGS. 1 and 4, method 100 includes a block 108 where an isolation feature 214 is formed around the fin-shaped base 212B of the fin-shaped structures 212. In some embodiments represented in FIG. 4, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 4. The fin-shaped structure 212 rises above the STI feature 214 after the recessing, while the fin-shaped base 212B is embedded or buried in the isolation feature 214.

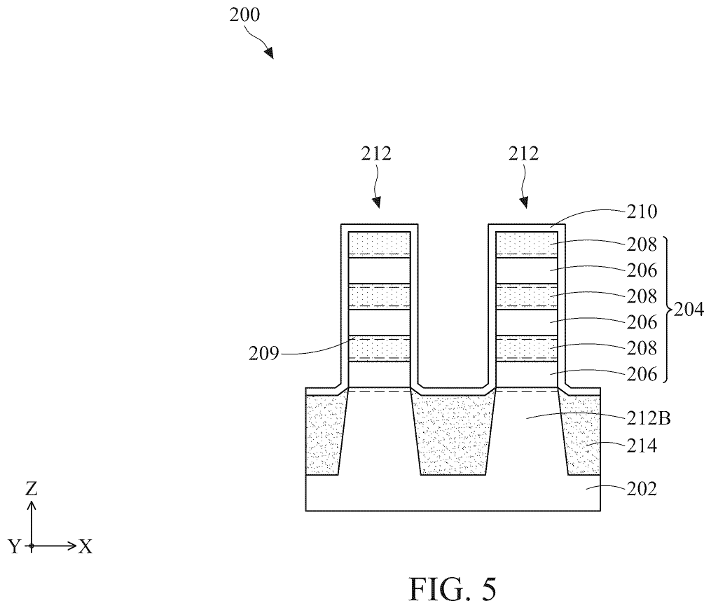

Referring to FIGS. 1 and 5, method 100 includes a block 110 where a semiconductor liner 210 is deposited over the fin-shaped structure 212. After the formation of the isolation feature 214, the semiconductor liner 210 may be deposited over the semiconductor device 200, including over the isolation feature 214, over a top surface of the fin-shaped structure 212, and along sidewalls of the fin-shaped structure 212. The semiconductor liner 210 functions to protect the sidewalls of the sacrificial layers 206 as it can sustain undesirable damages during the fabrication processes. In some embodiments, the semiconductor liner 210 may include silicon (Si). In some implementations, the semiconductor liner 210 may be deposited using PVD, CVD, or atomic layer deposition (ALD).

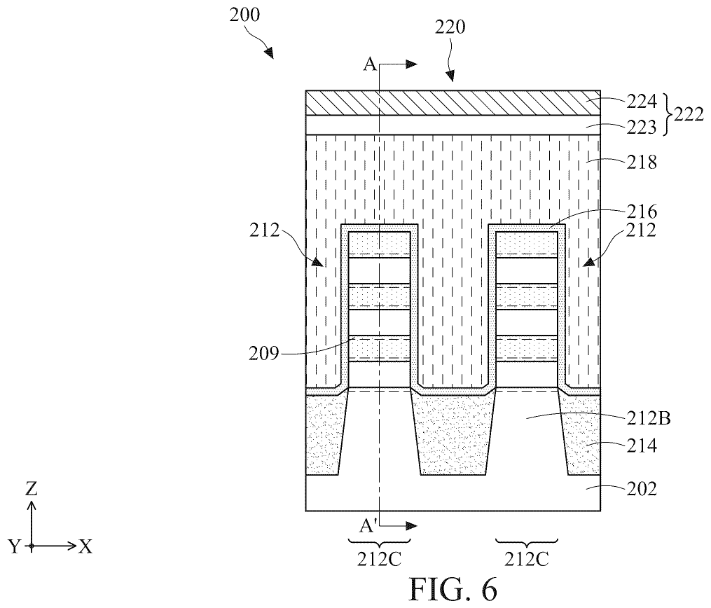

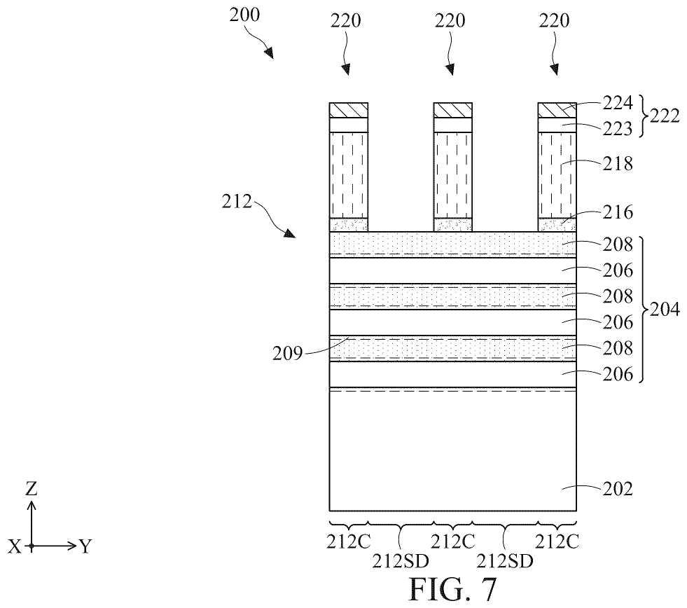

Referring to FIGS. 1 and 6-7, method 100 includes a block 112 where dummy gate stacks 220 are formed over a channel region 212C of the fin-shaped structure 212. The dummy gate stack 220 serves as a placeholder to undergo various processes and is to be removed and replaced by a functional gate structure. Other processes and configuration are possible. FIG. 7 is a cross-sectional view along the A-A line in FIG. 6. In some embodiments as illustrated in FIG. 7, the dummy gate stacks 220 are formed over the fin-shaped structure 212, and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 7, the channel region 212C is disposed between two source/drain regions 212SD along the Y direction. As used herein, a source/drain region, or “S/D region,” may refer to a region that provides a source and/or drain for one or multiple devices. It may also refer to a source or a drain of one or multiple devices.

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the semiconductor device 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 210 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 7, the dummy gate stack 220 is patterned such that it is only disposed over the channel region 212C, not disposed over the source/drain region 212SD.

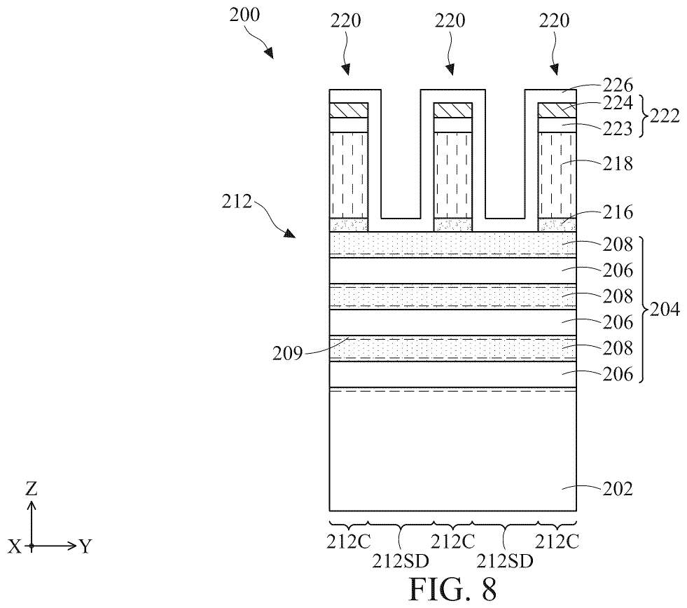

Referring to FIGS. 1 and 8, method 100 includes a block 114 where a gate spacer layer 226 is deposited over the semiconductor device 200, including over the dummy gate stack 220. In some embodiments, the gate spacer layer 226 is deposited conformally over the semiconductor device 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

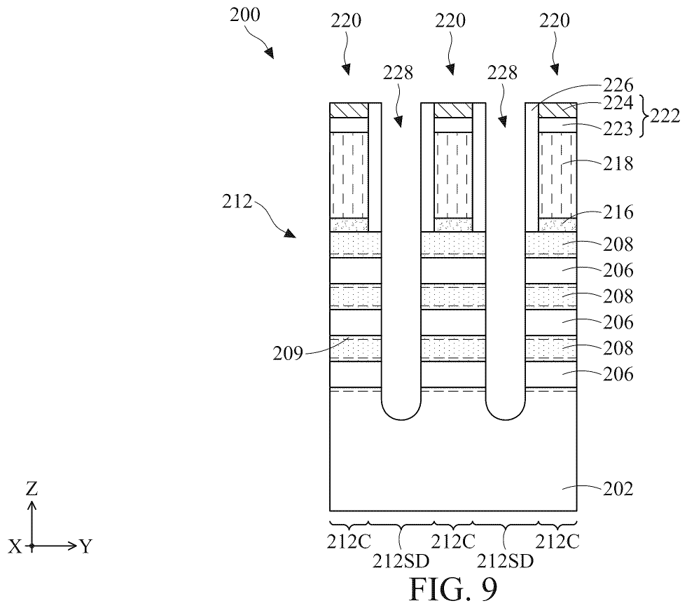

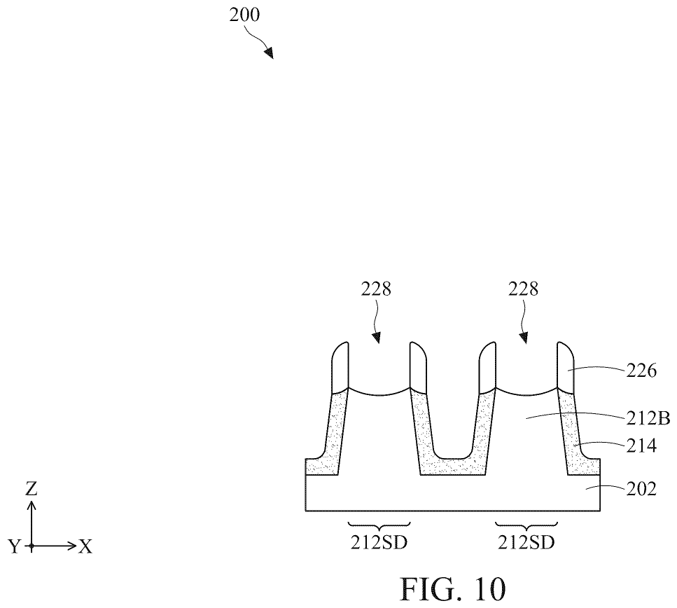

Referring to FIGS. 1 and 9-10, method 100 includes a block 116 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 116 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 9, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 10, which includes a fragmentary cross-sectional view across two adjacent source/drain regions 212SD. As shown in FIG. 10, over the source/drain regions 2126SD, the majority of the fin-shaped structure 212 is etched away and a top surface of the fin-shaped base 212B is exposed in the source/drain region 212SD. Because the gate spacer layer 226 is etched at a slower rate than the fin-shaped structure 212, the gate spacer layer 226 in the source/drain region 212SD rises above the top surface of the fin-shaped base 212B.

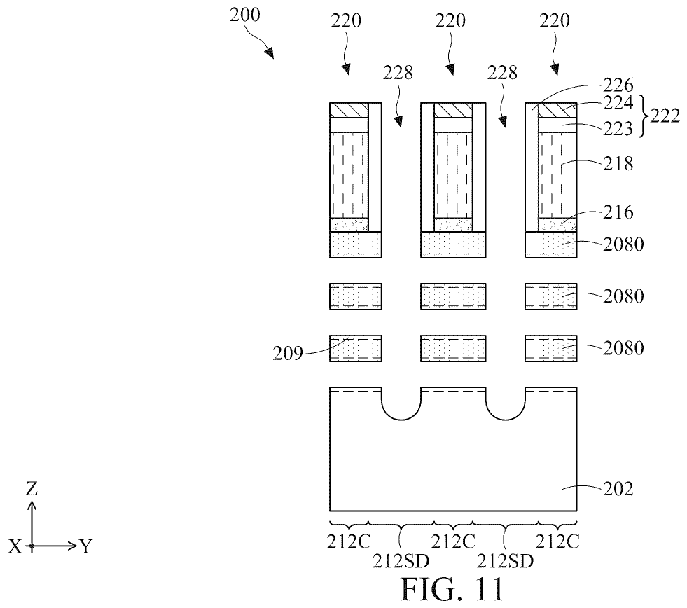

Referring to FIGS. 1 and 11, method 100 includes a block 118 where the plurality of channel layers 208 in the channel regions are released as channel members 2080. After the formation of the source/drain trenches 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 11. Depending on the design, the channel members 2080 may take form of nanowires, nanorods, nanosheets, or other nanostructures. The selective removal of the sacrificial layers 206 forms spaces between and around adjacent channel members 2080. The selective removal of the sacrificial layers 206 may be implemented by a selective dry etching process. An example selective dry etching process may include use of one or more fluorine-containing (F-containing) gas. In some embodiments, the fluorine-containing gas can include fluorine (F₂), hydrogen fluoride (HF), chlorine trifluoride (ClF₃), fluorine radical (F*), and nitrogen trifluoride radical (NF₃*). The germanium concentration difference between the sacrificial layers 206 and the intermixing layers 209 is carefully selected to provide proper etching selectivity. In some embodiments, the sacrificial layers 206 can be etched by a gas phase etching using fluorine-containing gases, such as F₂, HF, and ClF₃. In some embodiments, the sacrificial layers 206 can be etched by a radical phase etching using radicals, such as F*, H*, and NF₃*, generated from fluorine-containing gases by a remote plasma system. The dry etching process can have by-products, such as silicon tetrafluoride (SiF₄) and germanium tetrafluoride (GeF₄).

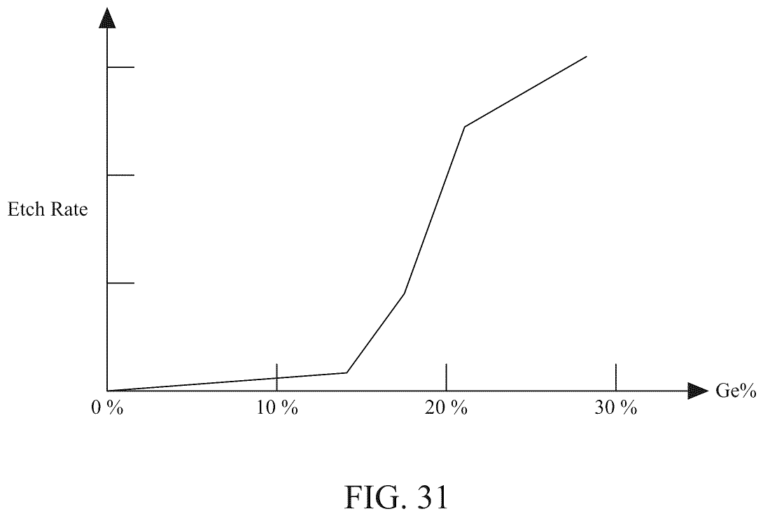

In some embodiments, the fluorine-containing gases can have a flow rate ranging from about 100 standard cubic centimeter per minute (sccm) to about 500 sccm. If the flow rate is less than about 100 sccm, the sacrificial layers 206 may not be etched by the fluorine-containing gases. If the flow rate is greater than about 500 sccm, etch rate of the fluorine-containing gases can increase and etch selectivity between the sacrificial layers 206 and the intermixing layers 209 may decrease. As a result, adjacent structures (e.g., the channel layers 208) may be damaged during the dry etching process. In some embodiments, the dry etching process can be performed at a temperature from about −20° C. to about 150° C. under a pressure from about 100 mTorr to about 1000 mTorr. If the temperature is less than about −20° C. and/or the pressure is less than about 100 mTorr, the sacrificial layers 206 may not be etched by the fluorine-containing gases. If the temperature is greater than about 150° C. and/or the pressure is greater than about 1000 mTorr, the etch rate of the fluorine-containing gases can increase and etch selectivity between the sacrificial layers 206 and the intermixing layers 209 may decrease. As a result, adjacent structures (e.g., the channel layers 208) may be damaged during the dry etching process. FIG. 31 illustrates an exemplary etch rate profile versus germanium atomic concentration (Ge %) based on etching parameters set in the ranges discussed above. As shown on the exemplary etch rate profile, when Ge % in the intermixing layers 209 is controlled in a range between about 0.02% and about 13% and Ge % in the sacrificial layers 206 is controlled in a range not less than about 20%, such as 30% or above, such that a ratio ranges between about 1:100 and about 1:5, a high etching selectivity can be achieved between the sacrificial layers 206 and the intermixing layers 209. In some embodiments, the intermixing layers 209 remain substantially intact after the removal of the sacrificial layers 206 and protect the channel layers 208 underneath from etching loss.

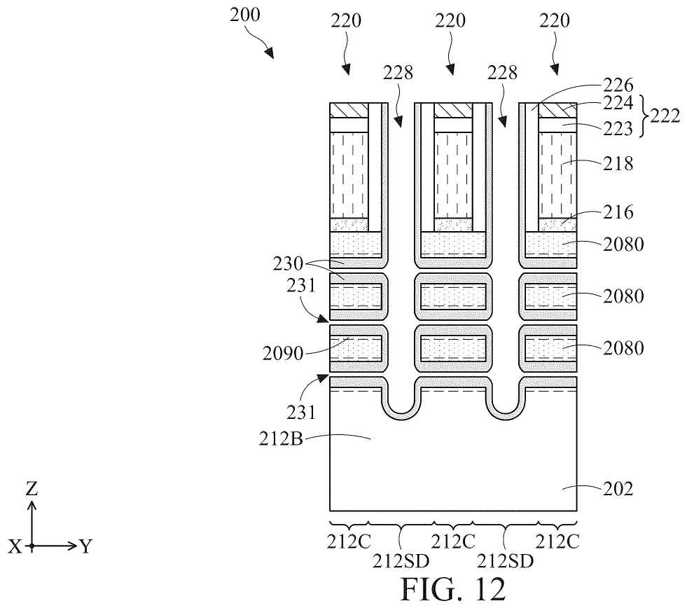

Referring to FIGS. 1 and 12-14, method 100 includes a block 120 where a dielectric dummy layer 230 is deposited around the channel members 2080 and over the source/drain trenches 228. The dielectric dummy layer 230 may be an oxide, such as SiOx in some embodiments. Other than using deposition processes such as flowable chemical vapor deposition (FCVD) and plasma-enhanced chemical vapor deposition (PECVD), which can quickly close the gaps between the channel members 2080 with voids and/or seams therebetween, the illustrated embodiment employs an ALD process with an organic precursor and O₃ to deposit silicon peroxide on various material surfaces (e.g., exposed surfaces of the channel members 2080, fin-shaped base 212B, isolation feature 214, gate spacer layer 226, etc.). This approach aims to improve gap-fill capability without leaving voids and/or seams. Specifically, as shown in FIG. 12 the ALD process deposits silicon peroxide to a proper thickness with a gap 231 intentionally left between the channel members 2080. That is, the ALD process forms an upper portion and a lower portion of the dielectric dummy layer 230 between two adjacent channel members 2080 with a gap 231 therebetween. The gap 231 may have a thickness in a range of about 0.5 nm to about 2 nm.

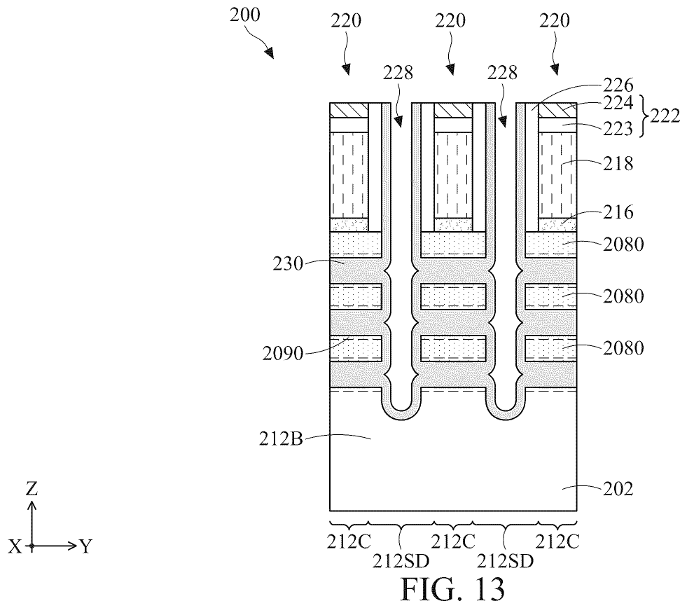

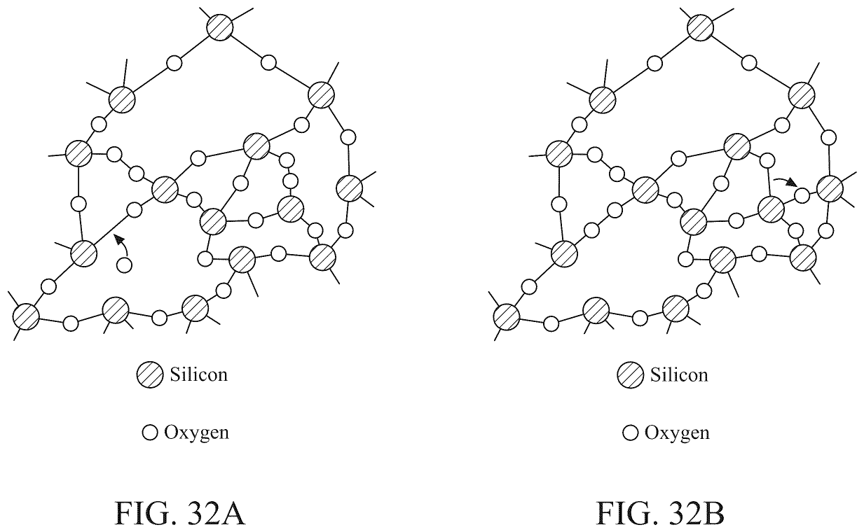

The characteristic structure of a peroxide is the oxygen-oxygen covalent single bond, which connects two silicon atoms together (Si—O—O—Si). FIG. 32A illustrates an exemplary molecular level structure of the dielectric dummy layer 230 deposited by the ALD process. The dielectric dummy layer 230 includes a combination of Si—O—O—Si group and Si—O—Si group. After the ALD process, method 100 at block 120 applies a cross-linking treatment to the silicon peroxide. The cross-linking treatment may be a thermal treatment to promote oxygen jump and electron-hole exchange (c/h exchange) at the molecular level of the peroxide. As shown in FIG. 32B, an oxygen atom in a Si—O—O—Si group may “jump” to a different location to create a Si—O—Si group linking two silicon atoms. The cross-linking treatment increases the Si—O—Si group concentration and reduces the Si—O—O—Si group concentration. During the cross-linking treatment, the dielectric dummy layer 230 starts to expand and eventually closes the gap 231 between the channel members 2080. Still further, after the gap 231 is closed, cross-linking reaction may continue to cross-link silicon atoms from the upper and lower portions of the dummy layer 230, such that different portions of the dummy layer 230 become a uniform material layer with no voids and/or seams therein. At the interface between the upper and lower portions of the dielectric dummy layer 230, the Si—O—Si group concentration is higher than Si—O—O—Si group concentration and also higher than either Si—O—Si group concentration or Si—O—O—Si group concentration in other portions of the dielectric dummy layer 230. As shown in FIG. 13, after the cross-linking treatment, the dielectric dummy layer 230 fills the space among the channel members 2080 and covers sidewalls of the channel members 2080. The combination of the ALD process and the cross-linking treatment improves gap fill capability without compromising production throughput. The dielectric dummy layer 230 is also in direct contact with sidewalls of the gate spacer layer 226 and the top surface of the substrate 202. In some alternative embodiments, the dielectric dummy layer 230 includes Si—O—C—N group. Additionally, as illustrated in FIG. 13, the intermixing layers 209 may be oxidized during the ALD process and the cross-linking treatment. The oxidation may be due to the intermixing layers 209 being exposed in the oxygen rich environment. As a result, the silicon germanium containing intermixing layers 209 are converted to silicon germanium oxide containing (Si_{1-x-y}GeₓO_{y}) layers, which are denoted as intermixing layers 2090 thereafter.

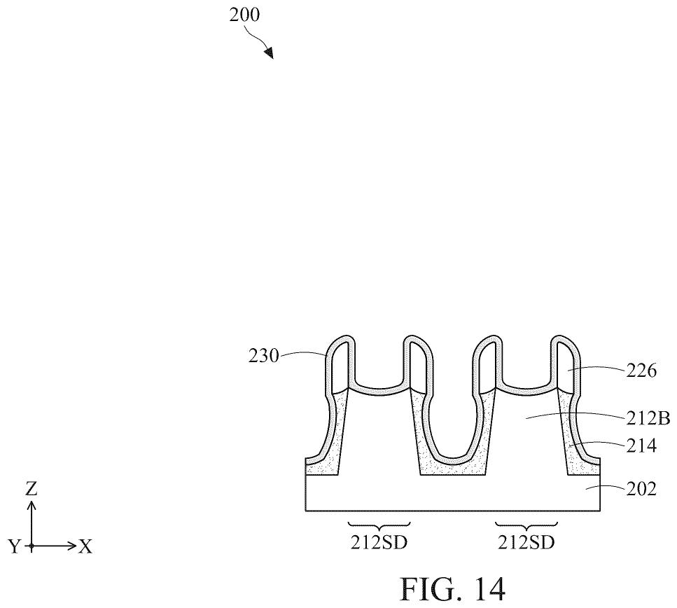

Reference is made to FIG. 14, which includes a fragmentary cross-sectional view across two adjacent source/drain regions 212SD. The dielectric dummy layer 230 extends over the isolation feature 214, sidewalls of the gate spacer layer 226, and top surfaces of the gate spacer layer 226. Due to the ALD process, a thickness of the dielectric dummy layer 230 at the bottom of the source/drain trench 228 may be substantially the same as a thickness of the dielectric dummy layer 230 along sidewalls of the gate spacer layer 226.

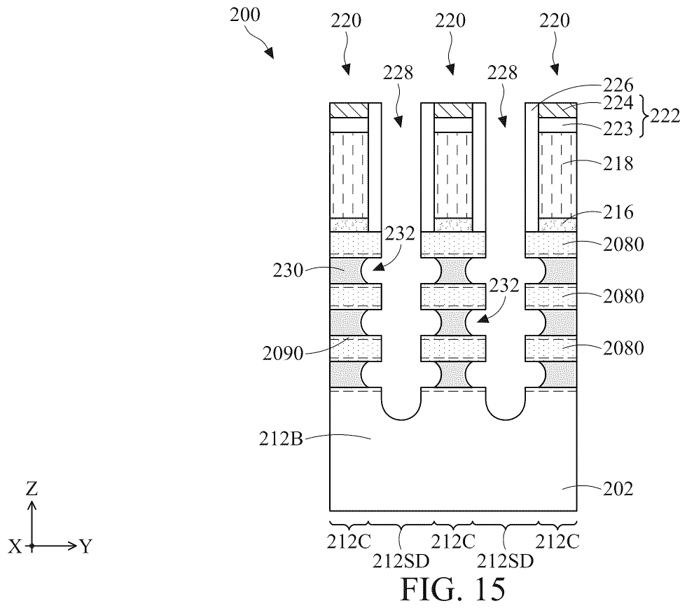

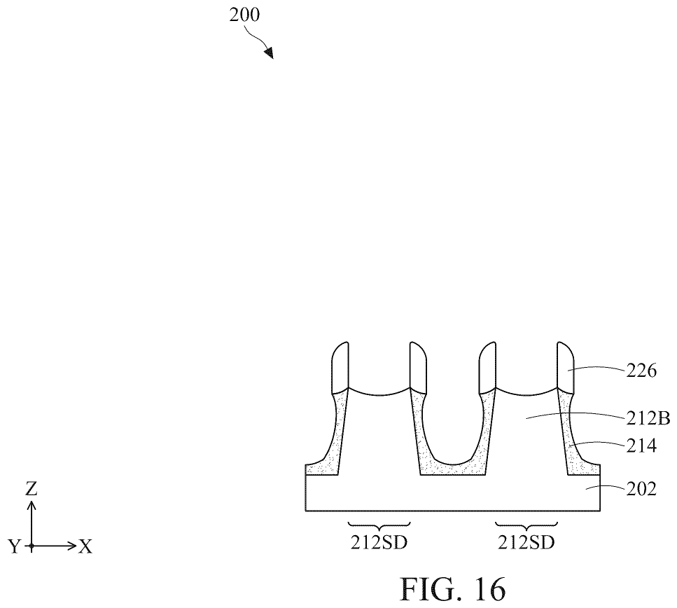

Referring to FIGS. 1 and 15-16, method 100 includes a block 122 where inner spacer recesses 232 are formed. Referring to FIG. 15, the dielectric dummy layers 230 are selectively and partially recessed to form inner spacer recesses 232. The inner spacer recesses 232 may have a concave profile bending away from the source/drain trenches 228. In an embodiment, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIG. 16, the dielectric dummy layer 230 is removed from the source/drain regions 212SD, and the fin-shaped base 212B is exposed.

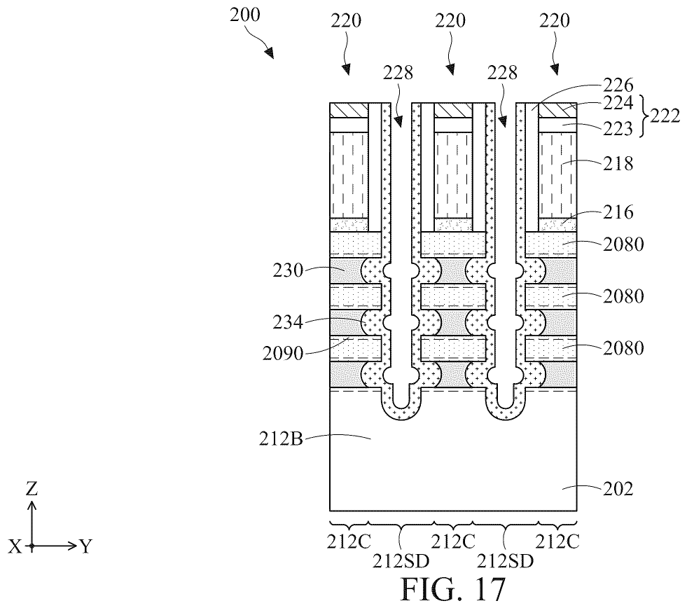

Referring to FIGS. 1 and 17, method 100 includes a block 124 where an inner spacer layer 234 is deposited over the inner spacer recesses 232. A composition of the inner spacer layer 234 is different from a composition of the dielectric dummy layer 230 to ensure that each one of them may be selectively etched without substantially damaging the other one. In some embodiments, the inner spacer layer 234 may include silicon carbonitride (SiCN), silicon oxycarbonitride (SiOCN), silicon nitride (SiN), silicon oxycarbide (SiOC), or silicon oxynitride (SiON). In some implementations, the inner spacer layer 234 may be deposited using CVD or ALD.

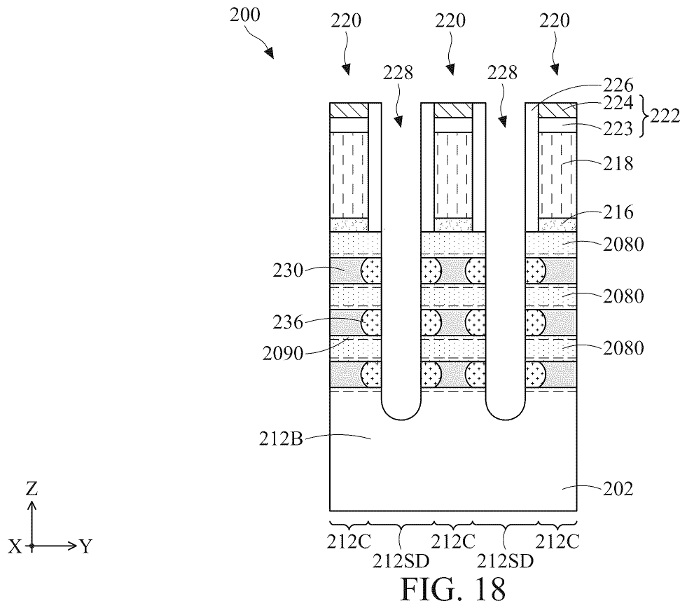

Referring to FIGS. 1 and 18, method 100 includes a block 126 where the inner spacer layer 234 is etched back to form inner spacer features 236 over the inner spacer recesses 232. In some embodiments, the etching back at block 124 may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacer features 236 laterally extend to a position directly under the dummy gate stack 220. Alternatively, the inner spacer features 236 may substantially remain under the gate spacer layer 226 without extending to a position directly under the dummy gate stack 220.

Referring to FIGS. 1 and 19-20, method 100 includes a block 128 where a buffer epitaxial layer 238 is deposited in the bottom of the source/drain trenches 228. The buffer epitaxial layer 238 is epitaxially grown from the top surface of the fin-shaped base 212B. By way of example, epitaxial growth of the buffer epitaxial layer 238 may be performed by VPE, ultra-high vacuum CVD (UHV-CVD), MBE, and/or other suitable epitaxial grow processes. In some embodiments, the buffer epitaxial layer 238 includes the same material as the substrate 202, such as silicon. In some alternative embodiments, the buffer epitaxial layer 238 includes a different semiconductor material other than silicon, such as SiGe, SiSn, or other suitable semiconductor material. In some embodiments, the buffer epitaxial layer 238 is dopant-free, where for example, no intentional doping is performed during the epitaxial growth process. As a comparison, in one instance, the substrate 202 is lightly doped and has a higher doping concentration than the buffer epitaxial layer 238. The buffer epitaxial layer 238 provides a high resistance path from the S/D regions to the semiconductor substrate, such that the leakage current in the semiconductor substrate is suppressed.

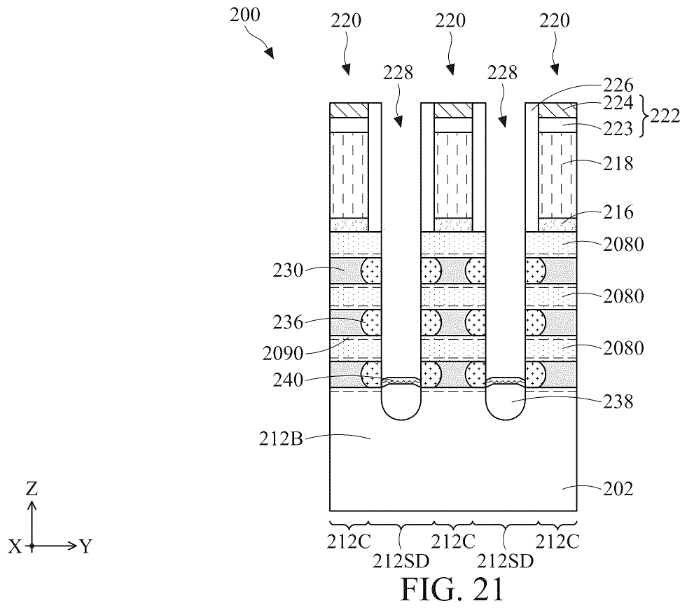

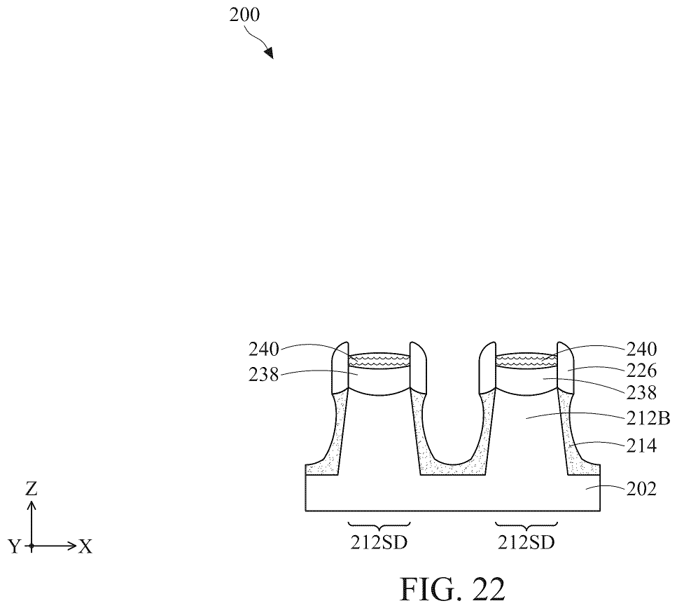

Referring to FIGS. 1 and 21-22, method 100 includes a block 130 where a bottom isolation layer 240 is formed over the buffer epitaxial layer 238. Because the bottom isolation layer 240 may interface source/drain features and oxygen content may oxidize source/drain features, the bottom isolation layer 240 may be formed of an oxygen-free dielectric material, such as nitrogen. In an example process, a chlorine-containing silicon nitride layer is deposited over the source/drain trenches 228, including over a top surface of the buffer epitaxial layer 238. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etching process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etching process etches the chlorine-containing silicon nitride along sidewalls faster than it does relatively chlorine-free silicon nitride layer at the bottom of the source/drain trenches 228, the bottom isolation layer 240 may be formed over the buffer epitaxial layer 238, as shown in FIGS. 21 and 22.

Referring to FIGS. 1 and 23-24, method 100 includes a block 132 where a source/drain feature 244 is formed over the source/drain region 212SD. While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment.

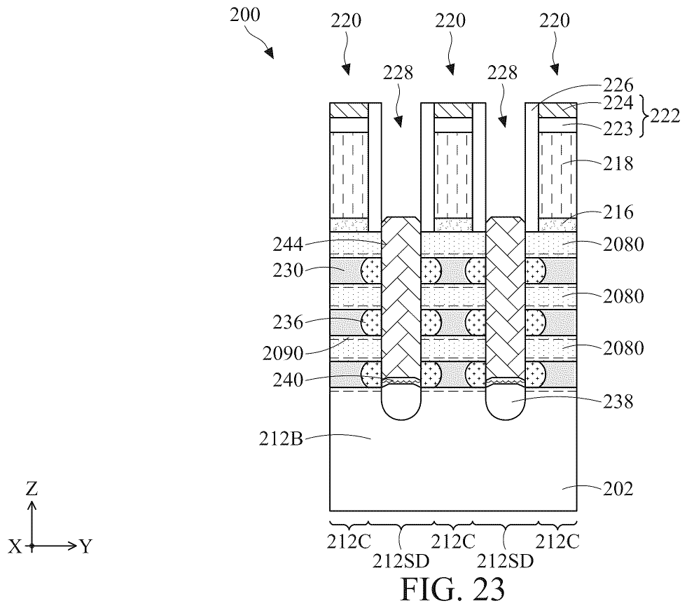

Reference is made to FIG. 23. The source/drain feature 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a lightly doped epitaxial feature over the bottom isolation layer 240 and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

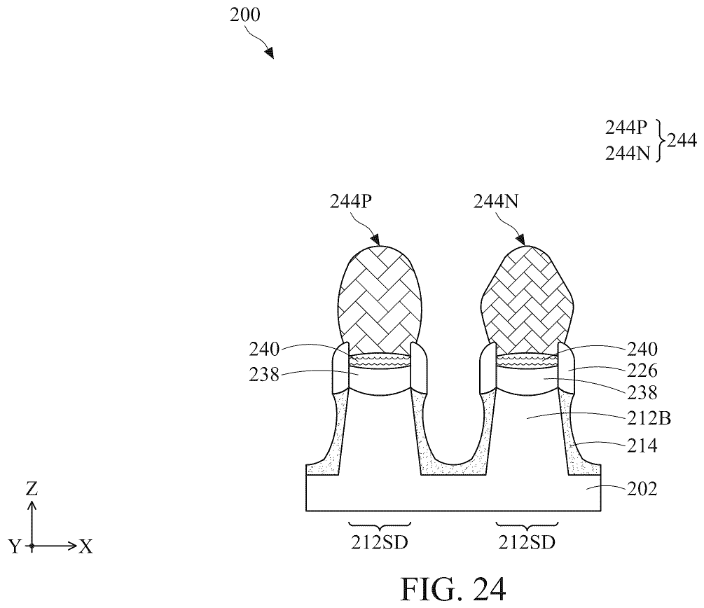

Reference is made to FIG. 24, which includes a fragmentary cross-sectional view across two adjacent source/drain regions 212SD. In some embodiments represented in FIG. 24, an n-type source/drain feature 244N may be adjacent to a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface of the bottom isolation layer 240. For case of illustration and description, the n-type source/drain feature 244N and the p-type source/drain feature 244P may be collectively referred to as the source/drain feature 244, as in FIG. 23.

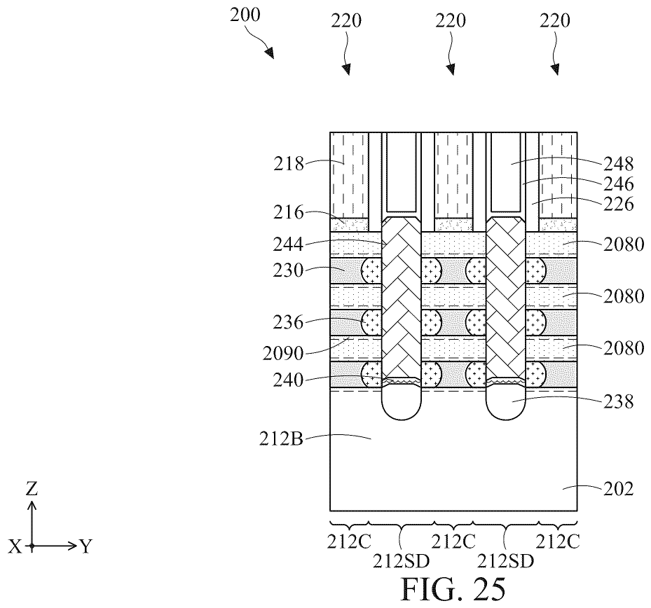

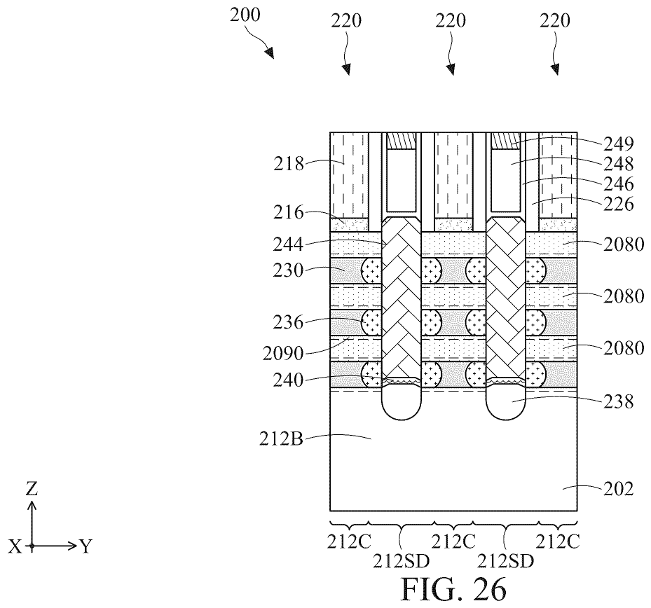

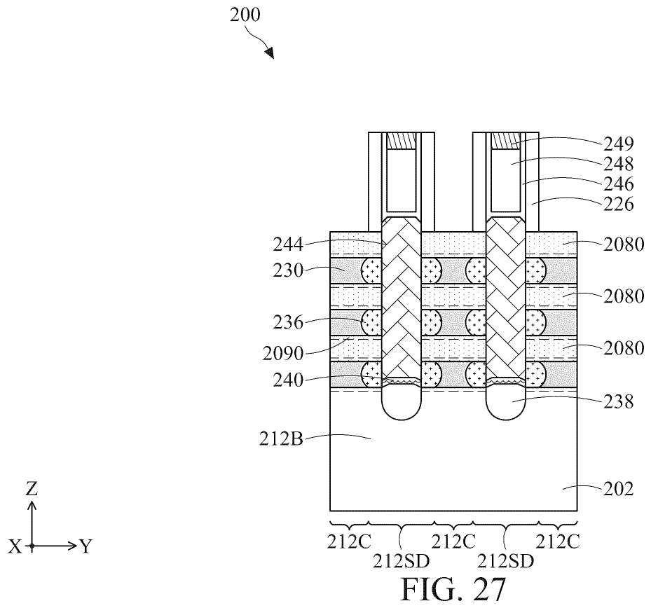

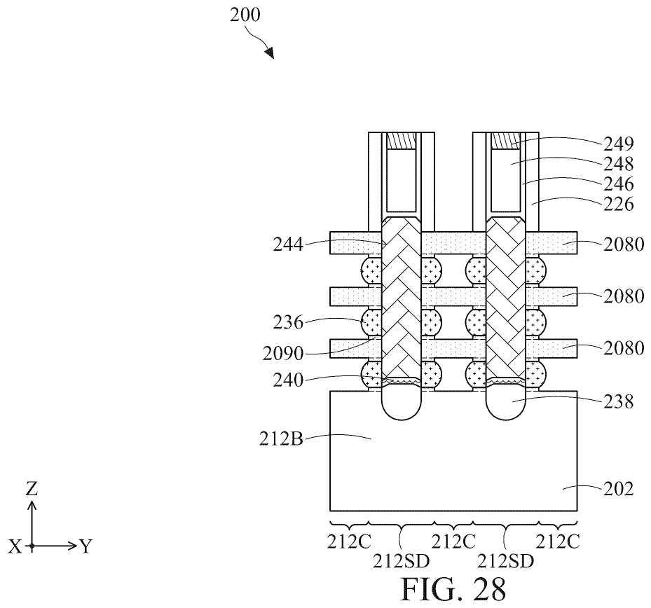

Referring to FIGS. 1 and 25-29, method 100 includes a block 134 where the dummy gate stack 220 and the dielectric dummy layer 230 are replaced with a gate structure 250. Operations at block 134 may include deposition of a contact etch stop layer (CESL) 246 over the source/drain features 244 (shown in FIG. 25), deposition of an interlayer dielectric (ILD) layer 248 over the CESL 246 (shown in FIG. 25), deposition of a capping layer 249 over the ILD layer 248 (shown in FIG. 26), removal of the dummy gate stack 220 (shown in FIG. 27), removal of the dielectric dummy layer 230 (shown in FIG. 28), and deposition of the gate structure 250 to wrap around each of the channel members 2080 (shown in FIG. 28).

Referring to FIG. 25, the CESL 246 is deposited over the semiconductor device 200, including over the source/drain feature 244. The CESL 246 may include silicon nitride or aluminum nitride. In some implementations, the CESL 246 may be deposited using CVD or atomic layer deposition (ALD). The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process.

Referring to FIG. 26, in order to protect the ILD layer 248 from being damaged during the dielectric dummy layer 230 removal step, the ILD layer 248 is selectively recessed to form a top recess and a capping layer 249 is formed over the top recess. The capping layer 249 is formed of a different material than the dielectric dummy layer 230. When the dielectric dummy layer 230 includes silicon oxide, the capping layer 249 is not formed of silicon oxide so as to ensure etching selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 246, the gate spacer layer 226, and the dummy gate stacks 220 are coplanar. Exposure of the dummy gate stack 220 allows the removal thereof. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

Referring to FIGS. 27 and 28, after the removal of the dummy gate stack 220, the dielectric dummy layer 230 in the channel region 212C is exposed, and subsequently a separate etching process may be performed to selectively remove the dielectric dummy layer 230 in the channel region 212C. For example, a selective wet etching process or a selective dry etching process may be performed to remove the dielectric dummy layer 230. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. The removal of the dielectric dummy layer 230 also removes the exposed portions of the intermixing layers 2090, as the intermixing layers 209 and the dielectric dummy layer 230 both include oxide. By design, the etch selectivity of the dielectric dummy layer 230 over the channel members 2080 may be larger than about 1000:1, such that the channel members 2080 remain substantially intact. After the selective removal of the dielectric dummy layer 230, the channel members 2080 in the channel region 212C are once again exposed. Since the channel members 2080 are protected from the previous etching processes as under the intermixing layers 2090 (previous 209), a surface roughness of the channel members 2080 after being exposed may be less than about 1 nm, and a sheet height loss of the channel members 2080 may be less than about 0.5 nm with a sheet height loading less than about 0.5 nm. In addition, a portion of the intermixing layers 2090 vertically stacked between the inner spacer features 236 and the channel members 2080, as well as between the bottommost inner spacer feature 236 and the substrate 202, also remains, as shown in FIG. 28. Notably, regarding the topmost channel member 2080, the remaining portion of the intermixing layer 2090 is under its bottom surface and not on its top surface. The remaining portion of the intermixing layer 2090 also directly interfaces sidewalls of the source/drain feature 244 and the buffer epitaxial layer 238. The intermixing layers 2090 include silicon germanium oxide (Si_{1-x-y}GeₓO_{y}). In some embodiments, x is in a range between about 0.02% and about 10%, y is in a range between about 1% to about 30%, and x is less than y (x<y). In the illustrated embodiment, the length of the intermixing layers 2090 measured in the Y direction is smaller than the length of the inner spacers features 236. The thickness of the intermixing layers 209 measured in the Z direction may be in the range between about 0.1 nm and about 2 nm, in some embodiments. In some embodiments, the bottommost one of the intermixing layers 209 is thick enough to have physical contact with both the buffer epitaxial layer 238 and the bottom isolation layer 240.

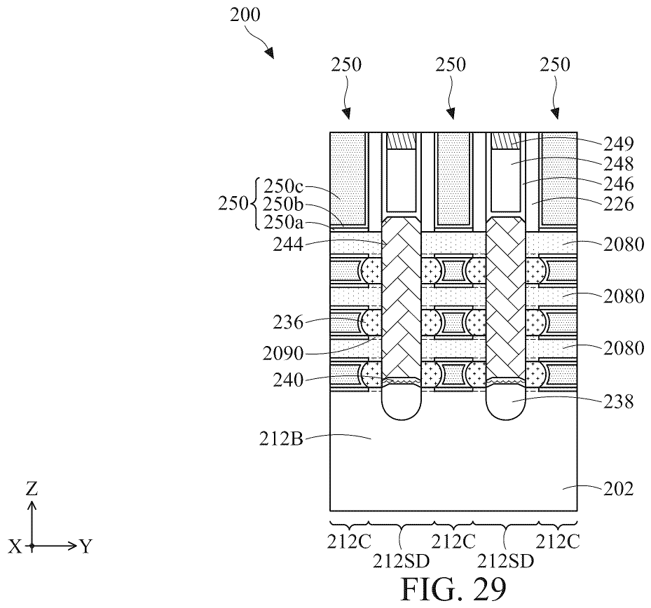

Referring to FIG. 29, after the release of the channel members 2080, the gate structure 250 is formed to wrap around each of the channel members 2080. The gate structure 250 is also referred to as metal gate structure 250 due to its metal-containing layers. In the depicted embodiment, the gate structure 250 includes an interfacial layer 250a interfacing the channel members 2080 and the substrate 202 in the channel region 212C, a high-k dielectric layer 250b over the interfacial layer 250a, and a gate electrode layer 250c over the high-k dielectric layer 250b. The interfacial layer 250a and the high-k dielectric layer 250b may be collectively referred to as the gate dielectric layer. The interfacial layer 250a may include a dielectric material such as silicon oxide, hafnium silicate, or silicon oxynitride. The interfacial layer 250a may be formed by chemical oxidation, thermal oxidation, atomic layer deposition (ALD), chemical vapor deposition (CVD), and/or other suitable method. The high-k dielectric layer 250b may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer 250b may be formed by ALD, physical vapor deposition (PVD), CVD, oxidation, and/or other suitable methods. The interfacial layer 250a may directly interface the remaining portion of the intermixing layer 2090. Depending on the thickness of the intermixing layer 2090 and the interfacial layer 250a, the high-k dielectric layer 250b may also directly interface the remaining portion of the intermixing layer 2090.

The gate electrode layer 250c of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 250c may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 250c may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

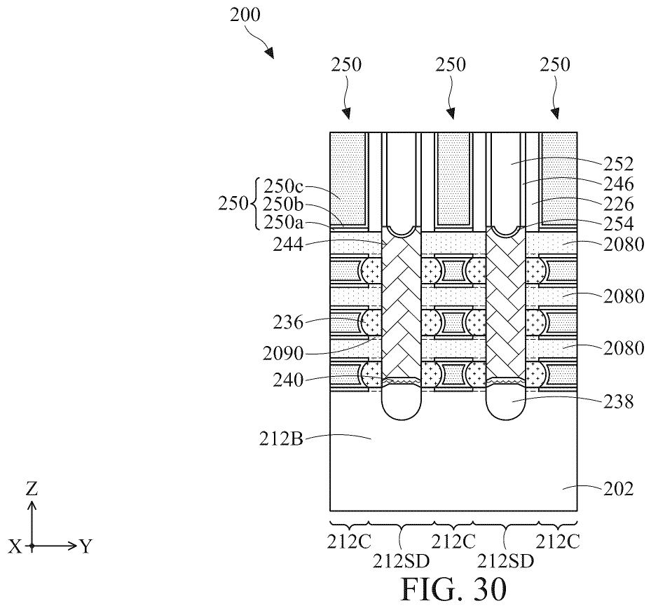

Referring to FIGS. 1 and 30, method 100 includes a block 136 where source/drain contact plugs 252 and optional silicide features 254 between the source/drain contact plugs 252 and the source/drain feature 244 are formed in the source/drain regions 212SD. In an exemplary process, contact holes are first formed by etching through the capping layer 249, the ILD layer 248, and the CESL 246. The etching process may be a self-aligned process such that the capping layer 249 and the ILD layer 248 are removed using the vertical sidewalls of the CESL 246 as an etch stop layer. An upper portion of the source/drain feature 244 may optionally be etched to have a concave shape as a bottom of the contact hole. In the depicted embodiment, the source/drain feature 244 is recessed to a position below the bottom surface of the topmost channel member 2080. The silicide features 254 are formed at the bottom of the contact holes. The silicide features 254 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, source/drain contact plugs 252 are formed on the silicide features 254. Each source/drain contact plug 252 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. The silicide feature 254 and the source/drain contact plug 252 may be collectively referred to as the source/drain contact.

Although not intended to be limiting, embodiments of the present disclosure provide one or more of the following advantages. For example, embodiments of the present disclosure replace germanium-containing sacrificial layers with oxide-containing dielectric dummy layers. During a replacement gate process, the dielectric dummy layers are selectively removed to release the channel members. A metal gate structure is then formed to wrap around each of the channel members. Such a process increases the etching contrast during the release of the channel members and improves the profile uniformity in the channel region of a GAA transistor. Further, embodiments of the present disclosure can be readily integrated into existing semiconductor manufacturing processes.

In one exemplary aspect, the present disclosure is directed to a method. The method includes forming over a substrate a stack that includes a plurality of channel layers interleaved by a plurality of sacrificial layers, patterning the stack to form a fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, selectively removing the sacrificial layers in the channel region to release the channel layers as channel members, partially filling a space vertically stacked between adjacent two of the channel members with a dielectric dummy layer, performing a treatment to expand the dielectric dummy layer, such that the space is fully filled by the dielectric dummy layer, laterally recessing the dielectric dummy layer to form inner spacer recesses, depositing an inner spacer layer over the inner spacer recesses, etching back the inner spacer layer to form inner spacer features in the inner spacer recesses, forming a source/drain feature in the source/drain region, after the forming of the source/drain feature, removing the dummy gate stack, removing the dielectric dummy layer to release the channel members, and forming a gate structure to wrap around each of the channel members. In some embodiments, the partially filling of the space includes depositing the dielectric dummy layer in an atomic layer deposition (ALD) process. In some embodiments, the treatment is a cross-linking treatment. In some embodiments, the dielectric dummy layer includes a peroxide. In some embodiments, the dielectric dummy layer includes Si—O—O—Si group and Si—O—Si group. In some embodiments, after the performing of the treatment, a concentration of the Si—O—O—Si group decreases, and a concentration of the Si—O—Si group increases. In some embodiments, the method further includes prior to the selectively removing of the sacrificial layers, forming intermixing layers between adjacent two of the channel layers and the sacrificial layers. In some embodiments, the intermixing layers have a germanium concentration lower than the sacrificial layers. In some embodiments, after the selectively removing of the sacrificial layers, the intermixing layers substantially remain. In some embodiments, prior to the selectively removing of the sacrificial layers, the intermixing layers are semiconductor layers, and wherein after the performing of the treatment, the intermixing layers are converted to oxide layers.

In another exemplary aspect, the present disclosure is directed to a method. The method includes forming over a substrate a stack that includes a plurality of silicon layers interleaved by a plurality of silicon germanium layers, performing a thermal treatment to grow a plurality of intermixing layers between adjacent two of the silicon layers and the silicon germanium layers, patterning the stack and a top portion of the substrate to form a fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, selectively removing the silicon germanium layers in the channel region to expose the intermixing layers, depositing an oxide layer in space among the silicon layers, partially recessing the oxide layer to form inner spacer recesses, forming inner spacer features in the inner spacer recesses, forming a source/drain feature in the source/drain trench, removing the dummy gate stack, selectively removing the oxide layer, and forming a gate structure to wrap around each of the silicon layers. In some embodiments, the intermixing layers include a germanium concentration less than about 13%, and the silicon germanium layers include a germanium concentration not less than about 20%. In some embodiments, the depositing of the oxide layer oxidizes the intermixing layers. In some embodiments, the selectively removing of the oxide layer also removes the intermixing layers. In some embodiments, the depositing of the oxide layer includes performing an atomic layer deposition (ALD) process. In some embodiments, the depositing of the oxide layer includes performing a treatment to expand a volume of the oxide layer. In some embodiments, the treatment is a cross-linking treatment.

In yet another exemplary aspect, the present disclosure is directed to a semiconductor structure. The semiconductor structure includes a plurality of nanostructures suspended above a substrate, a gate structure wrapping around each of the nanostructures, a gate spacer layer disposed on sidewalls of the gate structure, a source/drain feature abutting the nanostructures, inner spacer features interposed between the gate structure and the source/drain feature, and an oxide layer vertically stacked between the inner spacer features and the nanostructures. The oxide layer contains germanium. In some embodiments, the oxide layer also includes silicon. In some embodiments, the oxide layer includes a germanium concentration in a range between about 0.02% and about 10%.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack to form a fin-shaped structure;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
selectively removing the sacrificial layers in the channel region to release the channel layers as channel members;
partially filling a space vertically stacked between adjacent two of the channel members with a dielectric dummy layer;
performing a treatment to expand the dielectric dummy layer, such that the space is fully filled by the dielectric dummy layer;
laterally recessing the dielectric dummy layer to form inner spacer recesses;
depositing an inner spacer layer over the inner spacer recesses;
etching back the inner spacer layer to form inner spacer features in the inner spacer recesses;
forming a source/drain feature in the source/drain region;
after the forming of the source/drain feature, removing the dummy gate stack;
removing the dielectric dummy layer to release the channel members; and
forming a gate structure to wrap around each of the channel members.

2. The method of claim 1, wherein the partially filling of the space includes depositing the dielectric dummy layer in an atomic layer deposition (ALD) process.

3. The method of claim 1, wherein the treatment is a cross-linking treatment.

4. The method of claim 1, wherein the dielectric dummy layer includes a peroxide.

5. The method of claim 1, wherein the dielectric dummy layer includes Si—O—O—Si group and Si—O—Si group.

6. The method of claim 5, wherein after the performing of the treatment, a concentration of the Si—O—O—Si group decreases, and a concentration of the Si—O—Si group increases.

7. The method of claim 1, further comprising:
prior to the selectively removing of the sacrificial layers, forming intermixing layers between adjacent two of the channel layers and the sacrificial layers.

8. The method of claim 7, wherein the intermixing layers have a germanium concentration lower than the sacrificial layers.

9. The method of claim 7, wherein after the selectively removing of the sacrificial layers, the intermixing layers substantially remain.

10. The method of claim 7, wherein prior to the selectively removing of the sacrificial layers, the intermixing layers are semiconductor layers, and wherein after the performing of the treatment, the intermixing layers are converted to oxide layers.

11. A method, comprising:
forming over a substrate a stack that includes a plurality of silicon layers interleaved by a plurality of silicon germanium layers;
performing a thermal treatment to grow a plurality of intermixing layers between adjacent two of the silicon layers and the silicon germanium layers;
patterning the stack and a top portion of the substrate to form a fin-shaped structure;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
selectively removing the silicon germanium layers in the channel region to expose the intermixing layers;
depositing an oxide layer in space among the silicon layers;
partially recessing the oxide layer to form inner spacer recesses;
forming inner spacer features in the inner spacer recesses;
forming a source/drain feature in the source/drain trench;
removing the dummy gate stack;
selectively removing the oxide layer; and
forming a gate structure to wrap around each of the silicon layers.

12. The method of claim 11, wherein the intermixing layers include a germanium concentration less than about 13%, and the silicon germanium layers include a germanium concentration not less than about 20%.

13. The method of claim 11, wherein the depositing of the oxide layer oxidizes the intermixing layers.

14. The method of claim 11, wherein the selectively removing of the oxide layer also removes the intermixing layers.

15. The method of claim 11, wherein the depositing of the oxide layer includes performing an atomic layer deposition (ALD) process.

16. The method of claim 11, wherein the depositing of the oxide layer includes performing a treatment to expand a volume of the oxide layer.

17. The method of claim 16, wherein the treatment is a cross-linking treatment.

18. A semiconductor structure, comprising:
a plurality of nanostructures suspended above a substrate;
a gate structure wrapping around each of the nanostructures;
a gate spacer layer disposed on sidewalls of the gate structure;
a source/drain feature abutting the nanostructures;
inner spacer features interposed between the gate structure and the source/drain feature; and
an oxide layer vertically stacked between the inner spacer features and the nanostructures, wherein the oxide layer contains germanium.

19. The semiconductor structure of claim 18, wherein the oxide layer also includes silicon.

20. The semiconductor structure of claim 18, wherein the oxide layer includes a germanium concentration in a range between about 0.02% and about 10%.
